(19) United States
(12) Patent Application Publication
(10) Pub. No.: US 2025/0157977 A1
(43) Pub. Date: May 15, 2025

(54) SEMICONDUCTOR DEVICE

(71) Applicant: Mitsubishi Electric Corporation, Tokyo (JP)

(72) Inventors: Jun OKADA, Chiyoda-ku, Tokyo (JP); Tetsuo MOTOMIYA, Chiyoda-ku, Tokyo (JP); Kazunori TAGUCHI, Chiyoda-ku, Tokyo (JP)

(73) Assignee: Mitsubishi Electric Corporation, Tokyo (JP)

(21) Appl. No.: 18/835,918

(22) PCT Filed: Mar. 4, 2022
(86) PCT No.: PCT/JP2022/009498

§ 371 Date: Aug. 5, 2024

(51) Int. Cl. H01L 23/00; H01L 23/051; H01L 25/07

(52) U.S. Cl. CPC H01L 24/72; H01L 23/051; H01L 25/072; H01L 2224/72; H01L 2924/13091

(57) ABSTRACT

A semiconductor device includes: a first electrode plate; a first semiconductor chip disposed on the first electrode plate; a first plate electrode disposed on the first semiconductor chip; a first columnar electrode disposed on the first plate electrode; a first coil spring; a first stepped electrode having a first lower step portion disposed on the first columnar electrode and a first upper step portion disposed on the first lower step portion; a first insulating frame having a first side wall and a first upper wall continuous with an upper end of the first side wall; and a second electrode plate electrically connected to the first upper step portion are provided. The first columnar electrode is formed with a first through hole that penetrates the first columnar electrode in the thickness direction of the first electrode plate.

### TECHNICAL FIELD

The present disclosure relates to a semiconductor device.

### BACKGROUND ART

Japanese Patent Laying-Open No. 2002-57263 (PTL 1) describes a pressure-contact type semiconductor device. The semiconductor device described in PTL 1 includes a semiconductor pellet, a metal frame plate, a first frame support member, a second frame support member, a first insulating plate, a second insulating plate, a first main terminal plate, a second main terminal plate, a flexible frame plate, an alignment mechanism, and a bolt.

The metal frame plate is rectangular in a plan view. The first insulating plate is disposed on the metal frame plate. The first main terminal plate has a first base and a first external lead. The first base is disposed on the first insulating plate. The first external lead is connected to a first external terminal. The semiconductor pellet is disposed on the first base. Thus, the semiconductor pellet is electrically connected to the first external terminal. The second main terminal plate has a second base and a second external lead. The second base is disposed on the semiconductor pellet. The second external lead is connected to a second external terminal. Thus, the semiconductor pellet is electrically connected to the second external terminal. The second insulating plate is disposed on the second base.

The alignment mechanism is disposed on the second insulating plate. The metal frame plate has a first side surface and a second side surface. The second side surface is opposite to the first side surface. The first frame support member and the second frame support member extend upward from the first side surface and the second side surface, respectively, in the thickness direction of the metal frame plate. The first frame support member and the second frame support member are disposed to face each other with the alignment mechanism interposed therebetween. One end of the flexible frame plate is connected to the upper end of the first frame support member, and the other end thereof is connected to the upper end of the second frame support member. The flexible frame plate is formed with a screw hole that penetrates the flexible frame plate in the thickness direction.

The bolt is screwed in the screw hole. When the bolt is rotated, the tip of the bolt protrudes from the flexible frame plate and comes into contact with the alignment mechanism. Thus, the first insulating plate, the first base, the semiconductor pellet, the second base, and the second insulating plate are sandwiched between the alignment mechanism and the metal frame plate. Thereby, the pressure contact is achieved between the semiconductor pellet and the first main terminal plate and the second main terminal plate in the pressure-contact type semiconductor device according to PTL 1.

### CITATION LIST

### Patent Literature

PTL 1: Japanese Patent Laying-Open No. 2002-57263

### SUMMARY OF INVENTION

### Technical Problem

As described above, in the pressure-contact type semiconductor device according to PTL 1, an external pressure-contact mechanism that includes the metal frame plate, the alignment mechanism, the first frame support member, the second frame support member, the flexible frame plate, and the bolt is required to achieve the pressure contact between the semiconductor pellet and the first main terminal plate and the second main terminal plate.

The present disclosure has been made in view of the problems mentioned above in the prior art. More specifically, the present disclosure provides a semiconductor device capable of maintaining a pressing force toward a semiconductor chip without using an external pressure-contact mechanism.

### Solution to Problem

The semiconductor device according to the present disclosure includes: a first electrode plate; a first semiconductor chip disposed on the first electrode plate; a first plate electrode disposed on the first semiconductor chip; a first columnar electrode disposed on the first plate electrode; a first coil spring; a first stepped electrode having a first lower step portion disposed on the first columnar electrode and a first upper step portion disposed on the first lower step portion; a first insulating frame having a first side wall and a first upper wall continuous with an upper end of the first side wall; and a second electrode plate electrically connected to the first upper step portion. The first columnar electrode is formed with a first through hole that penetrates the first columnar electrode in a thickness direction of the first electrode plate. The first coil spring is disposed in the first through hole, and is compressed by the first plate electrode and the first lower step portion to generate a repulsive force that presses the first plate electrode toward the first semiconductor chip. The first upper wall is formed with a first through hole that penetrates the first upper wall in the thickness direction of the first electrode plate and is configured to allow the first upper step portion to pass therethrough so as to protrude from the first upper wall. A lower end of the first side wall is fixed to the first electrode plate in such a manner that the first semiconductor chip, the first plate electrode, the first columnar electrode, and the first lower step portion are sandwiched between the first upper wall and the first electrode plate.

### Advantageous Effects of Invention

According to the semiconductor device of the present disclosure, it is possible to maintain a pressing force toward the semiconductor chip without using the external pressure-contact mechanism.

### BRIEF DESCRIPTION OF DRAWINGS

FIG. 1 is an exploded front view of a semiconductor device 100;

FIG. 2 is an exploded perspective view of the semiconductor device 100;

FIG. 3 is a cross-sectional view of the semiconductor device 100;

FIG. 4 is a cross-sectional view of a semiconductor device 100 according to a modification;

FIG. 5 is a cross-sectional view of a semiconductor device 100A;

FIG. 6 is a plan view of a semiconductor device 100B;

FIG. 7 is a cross-sectional view of the semiconductor device 100B;

FIG. 8 is a cross-sectional view of a semiconductor device 100B according to a modification;

FIG. 9 is a cross-sectional view of a semiconductor device 100C;

FIG. 10 is a cross-sectional view of a semiconductor device 100D;

FIG. 11 is a cross-sectional view of a semiconductor device 100E; and

FIG. 12 is a plan view of a semiconductor device 100E.

### DESCRIPTION OF EMBODIMENTS

The details of embodiments of the present disclosure will be described with reference to the drawings. In the following drawings, the same or corresponding parts are denoted by the same reference numerals, and the description thereof will not be repeated. The following embodiments may be appropriately combined.

### First Embodiment

A semiconductor device according to a first embodiment will be described. The semiconductor device according to the first embodiment is defined as a semiconductor device 100.

### (Configuration of Semiconductor Device 100)

The configuration of the semiconductor device 100 will be described below.

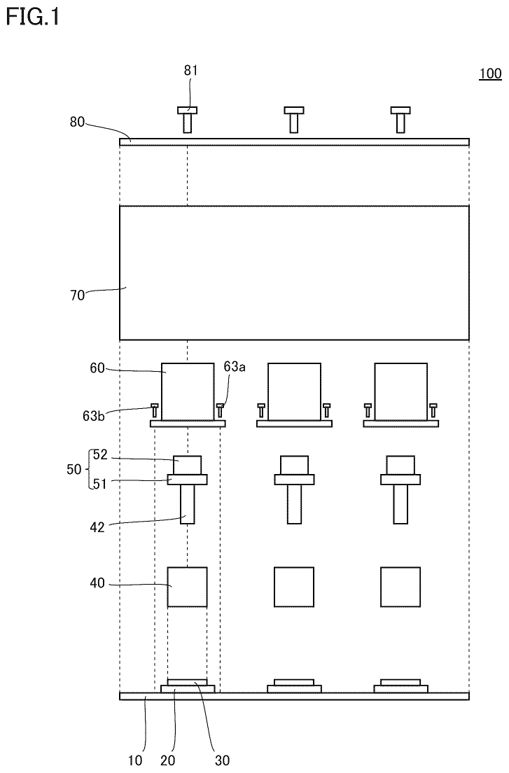

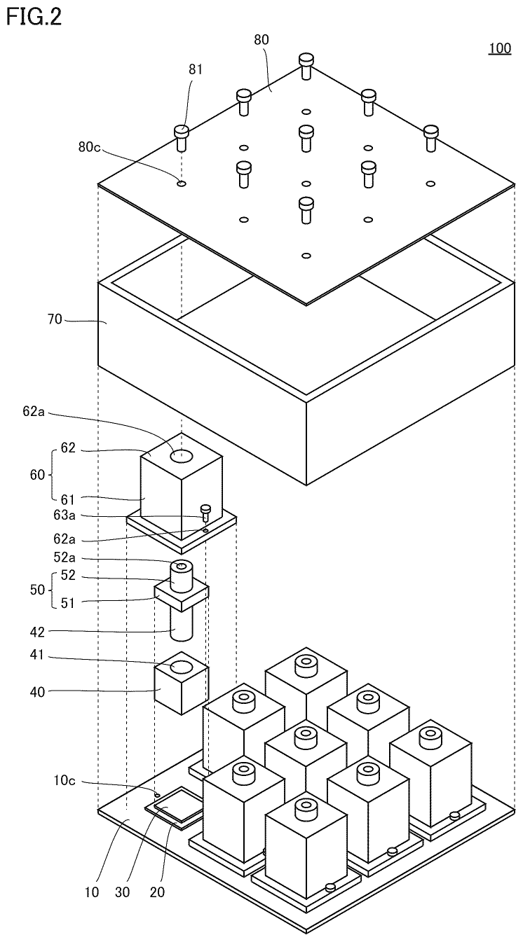

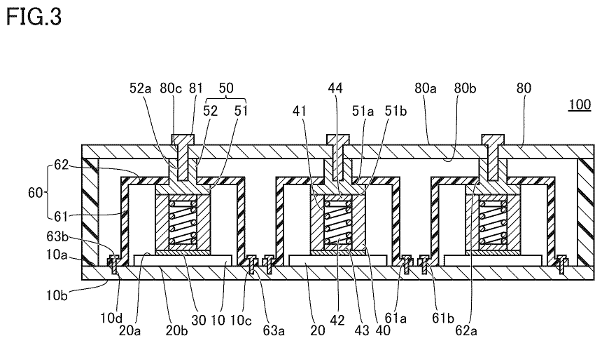

FIG. 1 is an exploded front view of the semiconductor device 100. FIG. 2 is an exploded perspective view of the semiconductor device 100. FIG. 3 is a cross-sectional view of the semiconductor device 100. As illustrated in FIGS. 1, 2 and 3, the semiconductor device 100 includes a first electrode plate 10, a plurality of semiconductor chips 20, a plurality of plate electrodes 30, a plurality of columnar electrodes 40, a plurality of stepped electrodes 50, a plurality of insulating frames 60, a module case 70, and a second electrode plate 80. The semiconductor device 100 is a pressure-contact type semiconductor device. The number of the plurality of plate electrodes 30, the number of the plurality of columnar electrodes 40, the number of the plurality of stepped electrodes 50, and the number of the plurality of insulating frames 60 are equal to the number of the plurality of semiconductor chips 20.

The first electrode plate 10 is a plate-shaped member. The first electrode plate 10 is made of a conductive material. The first electrode plate 10 is made of, for example, a metal material. The first electrode plate 10 has a first surface 10a and a second surface 10b. The first surface 10a and the second surface 10b are end surfaces in the thickness direction of the first electrode plate 10. The first surface 10a is formed with plural pairs of screw holes 10c and screw holes 10d. The screw hole 10c and the screw hole 10d are formed by, for example, tapping. Although not shown in the figures, the first electrode plate 10 is connected to an external electrode (a first external electrode) such as a bus bar. The first electrode plate 10 and the first external electrode are connected to each other by using a fastening member such as a screw.

The semiconductor chip 20 has a first surface 20a and a second surface 20b. The first surface 20a and the second surface 20b are end surfaces of the semiconductor chip 20 in the thickness direction. The first surface 20a is, for example, a surface on which a guard ring is formed. Although not shown in the figures, the semiconductor chip 20 has electrodes disposed on the first surface 20a and the second surface 20b. The semiconductor chip 20 is, for example, an IGBT (Insulated Gate Bipolar Transistor). However, the semiconductor chip 20 may be a MOSFET (Metal Oxide Semiconductor Field Effect Transistor), a gate turn-off transistor (GTO), a diode, or the like. In other words, the semiconductor chip 20 may be any device as long as it has electrodes disposed on the first surface 20a and the second surface 20b.

The semiconductor chip 20 is disposed on the first electrode plate 10. When the semiconductor chip 20 is disposed on the first electrode plate 10, the second surface 20b is in contact with the first surface 10a. The semiconductor chip 20 is disposed between the screw hole 10c and the screw hole 10d. A conductive material may be interposed between the second surface 20b and the first surface 10a to reduce contact resistance. The plurality of semiconductor chips 20 are arranged, for example, in a lattice shape in a plan view.

The plate electrode 30 is a plate-shaped member. The plate electrode 30 is made of a conductive material. The plate electrode 30 is made of, for example, a metal material. The plate electrode 30 is disposed on the semiconductor chip 20 (on the first surface 20a). A conductive material may be interposed between the plate electrode 30 and the semiconductor chip 20 to reduce contact resistance. The size of the plate electrode 30 in a plan view is appropriately selected in consideration of, for example, the current-carrying area of the semiconductor chip 20 (the area of the electrode on the first surface 20a).

The columnar electrode 40 has a column shape extending in the thickness direction of the first electrode plate 10. The columnar electrode 40 is made of a conductive material. The columnar electrode 40 is made of, for example, a metal material. The outer shape of the columnar electrode 40 is, for example, rectangular in a cross-sectional view orthogonal to the thickness direction of the first electrode plate 10. The columnar electrode 40 is disposed on the plate electrode 30. The columnar electrode 40 is formed with a through hole 41. The through hole 41 penetrates the columnar electrode 40 in the thickness direction of the first electrode plate 10. The through hole 41 has, for example, a circular shape in a cross-sectional view orthogonal to the thickness direction of the first electrode plate 10. The columnar electrode 40 may be integrally formed with the plate electrode 30.

A coil spring 42 is disposed in the through hole 41. The coil spring 42 extends spirally in the thickness direction of the first electrode plate 10. The coil spring 42 is compressed by the plate electrode 30 and a lower step portion 51 (a second surface 51b) to be described later to generate a repulsive force that presses the plate electrode 30 toward the semiconductor chip 20. A buffer member 43 may be disposed between the coil spring 42 and the plate electrode 30, and a buffer member 44 may be disposed between the coil spring 42 and the lower step portion 51. In order to suppress wear of the plate electrode 30 and the stepped electrode 50 due to the contact with the coil spring 42, the buffer member 43 and the buffer member 44 are preferably made of a material having high wear resistance. Specific examples of the materials for the buffer member 43 and the buffer member 44 include carbon steel, copper alloy, stainless steel or the like.

Using the coil spring 42 as a spring to apply a pressing force to the semiconductor chip 20, the semiconductor chip 20 can be substantially uniformly pressed as compared with a disc spring or the like. Even if the current-carrying area of the semiconductor chip 20 is different, it is possible to apply a uniform pressing force to the semiconductor chip 20 by selecting the number and the material of the coil springs 42 in accordance with the current-carrying area.

The stepped electrode 50 is made of a conductive material. The stepped electrode 50 is made of, for example, a metal material. The stepped electrode 50 includes a lower step portion 51 and an upper step portion 52. The lower step portion 51 has a first surface 51a and a second surface 51b. The first surface 51a and the second surface 51b are end surfaces of the lower step portion 51 in the thickness direction. The lower step portion 51 is disposed on the columnar electrode 40. The second surface 51b is in contact with the columnar electrode 40. In a cross-sectional view orthogonal to the thickness direction of the first electrode plate 10, the lower step portion 51 has, for example, a rectangular shape.

The upper step portion 52 is disposed on the lower step portion 51. In other words, the upper step portion 52 protrudes from the first surface 51a. In a plan view, the outer shape of the upper step portion 52 is smaller in size than the outer shape of the first surface 51a. In a cross-sectional view orthogonal to the thickness direction of the first electrode plate 10, the upper step portion 52 has, for example, a circular shape. The top surface of the upper step portion 52 is formed with a screw hole 52a. The screw hole 52a is formed by, for example, tapping.

The insulating frame 60 is made of an electrically insulating material. The insulating frame 60 is made of, for example, an insulating resin material. Specific examples of the insulating resin materials include epoxy resin and PPS (polyphenylene sulfide). The insulating frame 60 may be made of an insulating ceramic.

The insulating frame 60 has a side wall 61 and an upper wall 62. The side wall 61 surrounds the semiconductor chip 20, the plate electrode 30, the columnar electrode 40, and the stepped electrode 50 in a plan view. The side wall 61 is disposed on the first electrode plate 10 (the first surface 10a). The side wall 61 extends along the thickness direction of the first electrode plate 10. The upper wall 62 is continuous with the upper end of the side wall 61. The upper wall 62 is formed with a through hole 62a. The through hole 62a penetrates the upper wall 62 in the thickness direction of the first electrode plate 10. The upper step portion 52 is inserted in the through hole 62a. The first surface 51a is in contact with an inner wall surface of the upper wall 62 around the through hole 62a.

The lower end of the side wall 61 is fixed to the first electrode plate 10 (the first surface 10a). More specifically, a through hole 61a and a through hole 61b are formed in the vicinity of the lower end of the side wall 61. A fastening member 63a and a fastening member 63b are inserted in the through hole 61a and the through hole 61b, respectively. The fastening member 63a and the fastening member 63b are screws, bolts, or the like. The fastening member 63a and the fastening member 63b are screwed in the screw hole 10c and the screw hole 10d, respectively. As a result, the semiconductor chip 20, the plate electrode 30, the columnar electrode 40, and the lower step portion 51 are sandwiched between the upper wall 62 and the first electrode plate 10.

The module case 70 is made of an electrically insulating material. The module case 70 is made of, for example, an insulating resin material. Specific examples of the insulating resin materials include epoxy resin. The module case 70 may be made of an insulating ceramic. The module case 70 is disposed on an outer peripheral edge of the first electrode plate 10 (the first surface 10a). The module case 70 extends in the thickness direction of the first electrode plate 10.

The second electrode plate 80 is a plate-shaped member. The second electrode plate 80 is made of a conductive material. The second electrode plate 80 is made of, for example, a metal material. The second electrode plate 80 has a first surface 80a and a second surface 80b. The first surface 80a and the second surface 80b are end surfaces in the thickness direction of the second electrode plate 80. The second electrode plate 80 is disposed on the module case 70 in such a manner that the second surface 80b faces the first surface 10a with a space therebetween. In other words, the module case 70 is sandwiched between the first electrode plate 10 and the second electrode plate 80.

The second electrode plate 80 is formed with a plurality of through holes 80c. The through hole 80c is formed at a position overlapping with the screw hole 52a in a plan view. A fastening member 81 is inserted in the through hole 80c. Specifically, the fastening member 81 is screwed in the screw hole 52a. As a result, the second surface 80b around the through hole 80c comes into contact with the top surface of the upper step portion 52, whereby the second electrode plate 80 is electrically connected to the stepped electrode 50. Although not shown in the figures, an external electrode (a second external electrode) such as a bus bar is connected to the second electrode plate 80. The second electrode plate 80 and the second external electrode are connected to each other by using, for example, a fastening member such as a screw. The semiconductor device 100 is operated by supplying a current to the first external electrode and the second external electrode.

### (Effects of Semiconductor Device 100)

The effects of the semiconductor device 100 will be described below.

In the semiconductor device 100, the first electrode plate 10 and the second electrode plate 80 can be electrically connected to the semiconductor chip 20 without using any external pressure contact mechanism while maintaining a pressing force to the semiconductor chip 20. Since the external pressure contact mechanism is not necessary, it is possible to reduce the size of the semiconductor device 100. In the semiconductor device 100, an external connection electrode such as a bus bar can be easily connected to the first electrode plate 10 and the second electrode plate 80 by a fastening member or the like.

When an external pressure-contact mechanism is used to collectively press a plurality of semiconductor chips, the pressing force varies between the semiconductor chips disposed in the central portion and the semiconductor chips disposed in the outer peripheral portion. In the semiconductor device 100, since the pressing force is applied to each semiconductor chip 20 using the coil spring 42, the pressing force applied to the semiconductor chip 20 is less likely to vary in response to the position where the chip is disposed.

### (Modification)

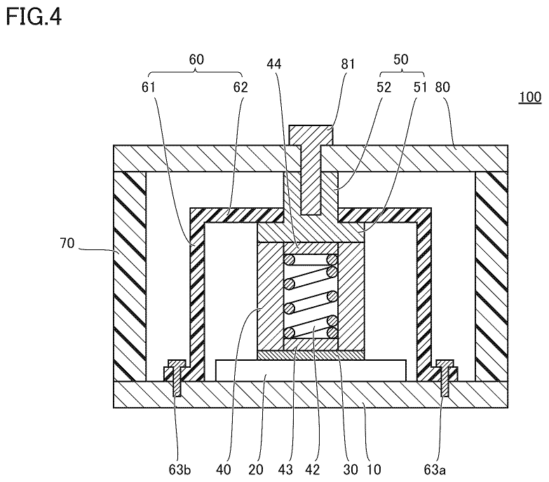

FIG. 4 is a cross-sectional view of a semiconductor device 100 according to a modification. In the above embodiment, it is described that the semiconductor device 100 includes a plurality of semiconductor chips 20. However, as illustrated in FIG. 4, the number of semiconductor chips 20 included in the semiconductor device 100 may be one.

### Second Embodiment

A semiconductor device according to a second embodiment will be described. The semiconductor device according to the second embodiment is defined as a semiconductor device 100A. Hereinafter, the differences from the semiconductor device 100 will be mainly described, and the description of the same components will not be repeated.

### (Configuration of Semiconductor Device 100A)

The configuration of the semiconductor device 100A will be described below.

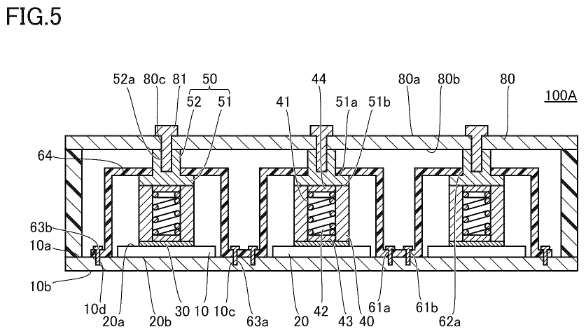

FIG. 5 is a cross-sectional view of the semiconductor device 100A. As illustrated in FIG. 5, the semiconductor device 100A includes a first electrode plate 10, a plurality of semiconductor chips 20, a plurality of plate electrodes 30, a plurality of columnar electrodes 40, a plurality of stepped electrodes 50, a module case 70, and a second electrode plate 80. In this regard, the configuration of the semiconductor device 100A is the same as the configuration of the semiconductor device 100. In the semiconductor device 100A, the plurality of insulating frames 60 are integrated to form an integrated insulating frame 64. In this regard, the configuration of the semiconductor device 100A is different from the configuration of the semiconductor device 100. It should be noted that in the semiconductor device 100A, the plurality of insulating frames 60 may be divided into a plurality of groups, and the insulating frames in each group may be integrated to form an integrated insulating frame 64.

### (Effects of Semiconductor Device 100A)

The effects of the semiconductor device 100A will be described below.

In the semiconductor device 100, since it is necessary to individually assemble the plurality of insulating frames 60, a plurality of steps are required for the assembly process. On the other hand, in the semiconductor device 100A, since the insulating frame 64 to be used is integrated from the plurality of insulating frames 60, it is possible to reduce the number of steps required for the assembly process.

### Third Embodiment

A semiconductor device according to a third embodiment will be described. The semiconductor device according to the third embodiment is defined as a semiconductor device 100B. Hereinafter, the differences from the semiconductor device 100 will be mainly described, and the description of the same components will not be repeated.

### (Configuration of Semiconductor Device 100B)

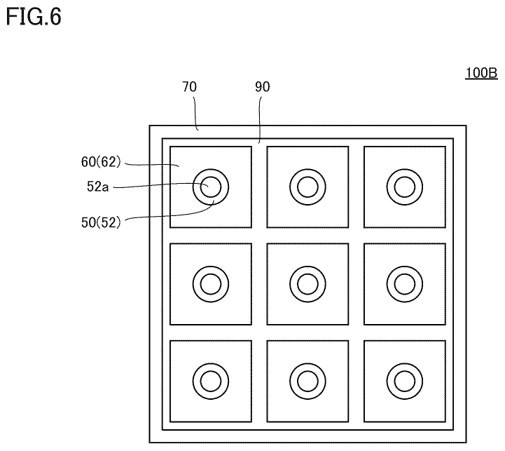

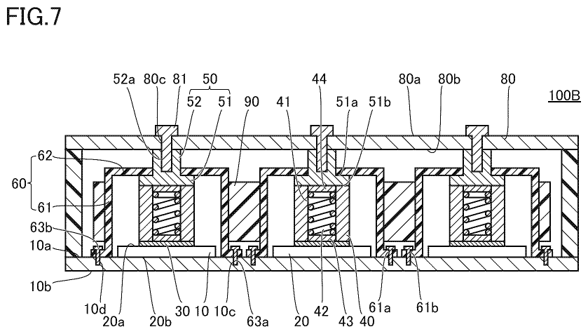

FIG. 6 is a plan view of the semiconductor device 100B. FIG. 7 is a cross-sectional view of the semiconductor device 100B. In FIG. 6, the second electrode plate 80 and the fastening member 81 are not illustrated. As illustrated in FIGS. 6 and 7, the semiconductor device 100B includes a first electrode plate 10, a plurality of semiconductor chips 20, a plurality of plate electrodes 30, a plurality of columnar electrodes 40, a plurality of stepped electrodes 50, a plurality of insulating frames 60, a module case 70, and a second electrode plate 80. In this regard, the configuration of the semiconductor device 100A is the same as the configuration of the semiconductor device 100.

The semiconductor device 100B further includes an outer peripheral frame 90. The outer peripheral frame 90 surrounds the outer periphery of the side wall 61 in a plan view. In other words, the outer peripheral frame 90 is formed with a plurality of openings arranged in a lattice shape in a plan view, and the side wall 61 is disposed in each opening. The outer peripheral frame 90 is disposed inside the module case 70 in a plan view. In order to prevent the semiconductor device 100B from becoming greater in size, it is preferable that the outer peripheral edge of the outer peripheral frame 90 coincides with the outer peripheral edge of the insulating frame 60 or is located inside the outer peripheral edge thereof in a plan view. It is preferable that the upper end and the lower end of the outer peripheral frame 90 are separated from the first electrode plate 10 and the second electrode plate 80, respectively. In these respects, the configuration of the semiconductor device 100B is different from the configuration of the semiconductor device 100.

### (Effects of Semiconductor Device 100B)

The effects of the semiconductor device 100B will be described below.

In the semiconductor device 100B, an energy that would destroy the semiconductor chip 20 may be absorbed by the outer peripheral frame 90. Further, since the upper end and the lower end of the outer peripheral frame 90 are separated from the first electrode plate 10 and the second electrode plate 80, respectively, it is not necessary to consider the creepage distance at the time of providing insulation between the first electrode plate 10 and the second electrode plate 80, which makes it possible to easily ensure the insulation between the first electrode plate 10 and the second electrode plate 80.

### (Modification)

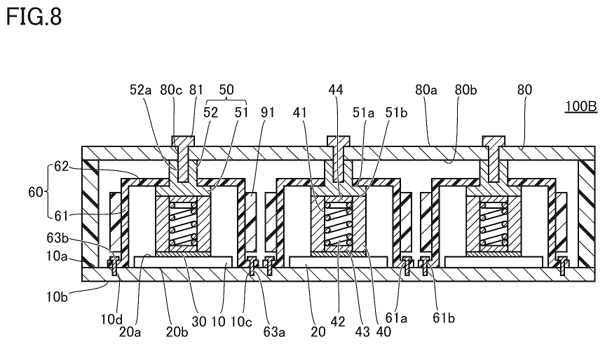

FIG. 8 is a cross-sectional view of a semiconductor device 100B according to a modification. In the above embodiment, it is described that the outer peripheral frame 90 is an integral member, but as illustrated in FIG. 8, the outer peripheral frame 90 may be divided into a plurality of outer peripheral frames 91. Each of the plurality of outer peripheral frames 91 surrounds the outer periphery of the side wall 61.

### Fourth Embodiment

A semiconductor device according to a fourth embodiment will be described. The semiconductor device according to the fourth embodiment is defined as a semiconductor device 100C. Hereinafter, the differences from the semiconductor device 100 will be mainly described, and the description of the same components will not be repeated.

### (Configuration of Semiconductor Device 100C)

The configuration of the semiconductor device 100C will be described below.

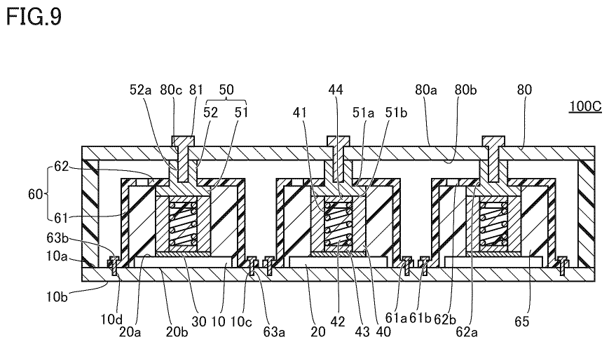

FIG. 9 is a cross-sectional view of the semiconductor device 100C. As illustrated in FIG. 9, the semiconductor device 100C includes a first electrode plate 10, a plurality of semiconductor chips 20, a plurality of plate electrodes 30, a plurality of columnar electrodes 40, a plurality of stepped electrodes 50, a plurality of insulating frames 60, a module case 70, and a second electrode plate 80. In this regard, the configuration of the semiconductor device 100C is the same as the configuration of the semiconductor device 100.

In the semiconductor device 100C, the upper wall 62 is formed with a through hole 62b. The number of the through holes 62b is preferably plural. The inside of the insulating frame 60 may be filled with a sealing resin 65. The sealing resin 65 is made of an insulating resin material. The sealing resin 65 is preferably soft. In these respects, the configuration of the semiconductor device 100C is different from the configuration of the semiconductor device 100.

### (Effects of Semiconductor Device 100C)

The effects of the semiconductor device 100C will be described below.

In the semiconductor device 100C, since the sealing resin 65 is supplied into the insulating frame 60 through the through hole 62b, it is possible to further improve the insulating property of the semiconductor chip 20. Further, in the semiconductor device 100C, gas generated when the semiconductor chip 20 is short-circuited can be discharged through the through hole 62b.

### Fifth Embodiment

A semiconductor device according to a fifth embodiment will be described. The semiconductor device according to the fifth embodiment is defined as a semiconductor device 100D. Hereinafter, the differences from the semiconductor device 100 will be mainly described, and the description of the same components will not be repeated.

### (Configuration of Semiconductor Device 100D)

The configuration of the semiconductor device 100D will be described below.

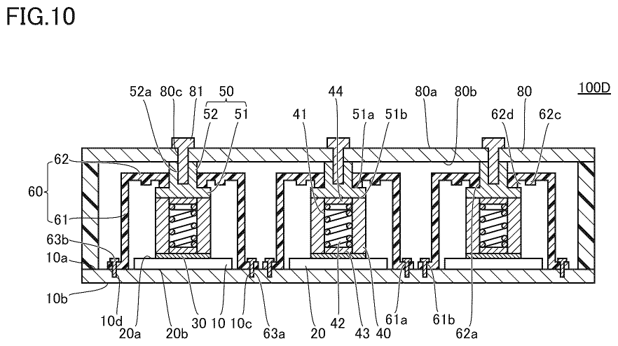

FIG. 10 is a cross-sectional view of the semiconductor device 100D. As illustrated in FIG. 10, the semiconductor device 100D includes a first electrode plate 10, a plurality of semiconductor chips 20, a plurality of plate electrodes 30, a plurality of columnar electrodes 40, a plurality of stepped electrodes 50, a plurality of insulating frames 60, a module case 70, and a second electrode plate 80. In this regard, the configuration of the semiconductor device 100D is the same as the configuration of the semiconductor device 100.

In the semiconductor device 100D, an inner wall surface of the upper wall 62 is formed with irregularities. More specifically, in the semiconductor device 100D, the inner wall surface of the upper wall 62 is formed with a plurality of convex portions 62c separated from each other with an interval, whereby the portion between two adjacent convex portions 62c becomes a concave portion 62d. In this regard, the configuration of the semiconductor device 100D is different from the configuration of the semiconductor device 100.

### (Effects of Semiconductor Device 100D)

The effects of the semiconductor device 100D will be described below.

In the semiconductor device 100, the creepage distance between the stepped electrode 50 and the first electrode plate 10 is shorter on the inner wall surface of the insulating frame 60 than on the outer wall surface of the insulating frame 60. On the other hand, in the semiconductor device 100D, since the irregularities (the convex portion 62c and the concave portion 62d) are formed on the upper wall 62, the creepage distance between the stepped electrode 50 and the first electrode plate 10 on the outer wall surface of the insulating frame 60 becomes greater. Therefore, according to the semiconductor device 100D, it is possible to further ensure the insulation between the stepped electrode 50 and the first electrode plate 10, which makes it possible to ensure the insulation of a product requiring higher insulation.

### Sixth Embodiment

A semiconductor device according to a sixth embodiment will be described. The semiconductor device according to the sixth embodiment is defined as a semiconductor device 100E. Hereinafter, the differences from the semiconductor device 100C will be mainly described, and the description of the same components will not be repeated.

### (Configuration of Semiconductor Device 100E)

The configuration of the semiconductor device 100E will be described below.

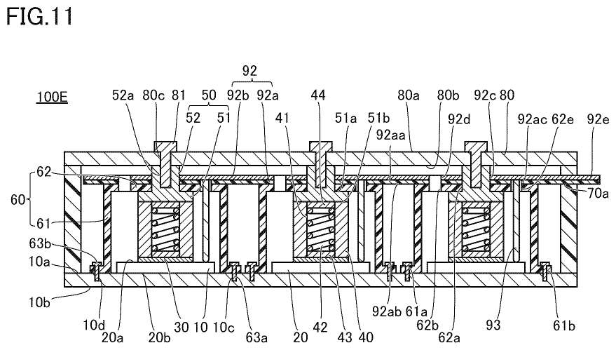

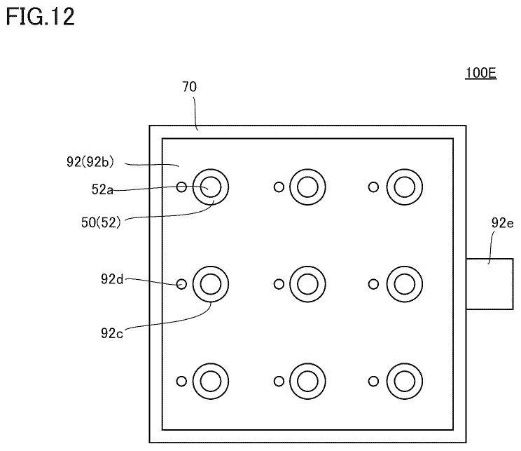

FIG. 11 is a cross-sectional view of the semiconductor device 100E. FIG. 12 is a plan view of the semiconductor device 100E. In FIG. 12, the second electrode plate 80 and the fastening member 81 are not illustrated. As illustrated in FIGS. 11 and 12, the semiconductor device 100E includes a first electrode plate 10, a plurality of semiconductor chips 20, a plurality of plate electrodes 30, a plurality of columnar electrodes 40, a plurality of stepped electrodes 50, a plurality of insulating frames 60, a module case 70, and a second electrode plate 80. In the semiconductor device 100E, the upper wall 62 is formed with a through hole 62b. In these respects, the configuration of the semiconductor device 100C is the same as the configuration of the semiconductor device 100C.

In the semiconductor device 100E, the upper wall 62 is formed with a through hole 62e. The through hole 62e penetrates the upper wall 62 in the thickness direction of the first electrode plate 10. The semiconductor device 100E further includes an insulating substrate 92 and a plurality of contact pins 93. The insulating substrate 92 includes a base 92a and a conductive pattern 92b.

The base 92a is made of an electrically insulating material. The base 92a has a first surface 92aa and a second surface 92ab. The first surface 92aa and the second surface 92ab are end surfaces of the base 92a in the thickness direction. The base 92a is disposed on the upper wall 62. The second surface 92ab faces the upper wall 62. The conductive pattern 92b is disposed on the first surface 92aa. The base 92a is formed with a plurality of through holes 92ac. The through hole 92ac penetrates the base 92a in the thickness direction of the first electrode plate 10. The through hole 92ac overlaps with the through hole 62e in a plan view.

The contact pin 93 is inserted in the through hole 62e and the through hole 92ac. The contact pin 93 is made of a conductive material. One end of the contact pin 93 is in contact with the conductive pattern 92b, and the other end of the contact pin 93 is in contact with the semiconductor chip 20 (the first surface 20a). Thus, the insulating substrate 92 is electrically connected to the semiconductor chip 20. When the plate electrode 30 is in contact with an emitter electrode formed on the first surface 20a, the other end of the contact pin 93 is in contact with a gate electrode formed on the first surface 20a. The other end of the contact pin 93 is preferably a spring contact.

The insulating substrate 92 is formed with a plurality of through holes 92c and a plurality of through holes 92d. The through hole 92c and the through hole 92d penetrate the insulating substrate 92 in the thickness direction of the first electrode plate 10. The through hole 92c overlaps with the through hole 62a in a plan view. The upper step portion 52 is inserted in the through hole 92c and the through hole 62a. The through hole 92d overlaps with the through hole 62b in a plan view. The insulating substrate 92 has a lead 92e. The lead 92e is drawn out of the module case 70 through a through hole 70a formed in the module case 70. An external electrode (a third external electrode) is connected to the conduction pattern 92b of the lead 92e.

### (Effects of Semiconductor Device 100E)

The effects of the semiconductor device 100E will be described below.

In the semiconductor device 100E, the semiconductor chip 20 and the insulating substrate 92 are electrically connected to each other by the contact pins 93. The insulating substrate 92 has a lead 92e that is drawn out of the module case 70. Therefore, according to the semiconductor device 100E, by connecting the third external electrode to the conduction pattern 92b of the lead 92e, it is possible to easily input and output an external signal.

It should be understood that the embodiments disclosed herein are illustrative and non-restrictive in all respects. The scope of the present invention is defined by the terms of the claims rather than the description of the embodiments above, and is intended to include any modifications within the scope and meaning equivalent to the terms of the claims.

### REFERENCE SIGNS LIST

10: first electrode plate; 10a: first surface; 10b: second surface; 10c, 10d: screw hole; 20: semiconductor chip; 20a: first surface; 20b: second surface; 30: plate electrode; 40: columnar electrode; 41: through hole; 42: coil spring; 43, 44: buffer member; 50: stepped electrode; 51: lower step portion; 51a: first surface; 51b: second surface; 52: upper step portion; 52a: screw hole; 60: insulating frame; 61: side wall; 61a, 61b: through hole; 62: upper wall; 62a, 62b: through hole; 62c: convex portion; 62d: concave portion; 62e: through hole; 63a, 63b: fastening member; 64: insulating frame; 65: sealing resin; 70: module case; 70a: through hole; 80: second electrode plate; 80a: first surface; 80b: second surface; 80c: through hole; 81: fastening member; 90, 91: peripheral frame; 92: insulating substrate; 92a: base; 92aa: first face; 92ab: second face; 92ac: through hole; 92b: conductive pattern; 92c, 92d: through hole; 92e: lead; 93: contact pin; 100, 100A, 100B, 100C, 100D, 100E: semiconductor device.

1. A semiconductor device comprising:
a first electrode plate;
a first semiconductor chip disposed on the first electrode plate;
a first plate electrode disposed on the first semiconductor chip;
a first columnar electrode disposed on the first plate electrode;
a first coil spring;
a first stepped electrode having a first lower step portion disposed on the first columnar electrode and a first upper step portion disposed on the first lower step portion;
a first insulating frame having a first side wall and a first upper wall continuous with an upper end of the first side wall; and
a second electrode plate electrically connected to the first upper step portion,
wherein the first columnar electrode is formed with a first through hole that penetrates the first columnar electrode in a thickness direction of the first electrode plate,
the first coil spring is disposed in the first through hole, and is compressed by the first plate electrode and the first lower step portion to generate a repulsive force that presses the first plate electrode toward the first semiconductor chip,
the first upper wall is formed with a first through hole that penetrates the first upper wall in the thickness direction of the first electrode plate and is configured to allow the first upper step portion to pass therethrough so as to protrude from the first upper wall, and
a lower end of the first side wall is fixed to the first electrode plate in such a manner that the first semiconductor chip, the first plate electrode, the first columnar electrode, and the first lower step portion are sandwiched between the first upper wall and the first electrode plate.

2. The semiconductor device according to claim 1, further comprising:
a second semiconductor chip disposed on the first electrode plate;
a second plate electrode disposed on the second semiconductor chip;
a second columnar electrode disposed on the second plate electrode;
a second coil spring;
a second stepped electrode having a second lower step portion disposed on the second columnar electrode and a second upper step portion disposed on the second lower step portion; and
a second insulating frame having a second side wall and a second upper wall continuous with an upper end of the second side wall,
wherein the second columnar electrode is formed with a second through hole that penetrates the second columnar electrode in the thickness direction of the first electrode plate,
the second coil spring is disposed in the second through hole, and is compressed by the second plate electrode and the second lower step portion to generate a repulsive force that presses the second plate electrode toward the second semiconductor chip,
the second upper wall is formed with a second through hole that penetrates the second upper wall in the thickness direction of the first electrode plate and is configured to allow the second upper step portion to pass therethrough so as to protrude from the second upper wall,
a lower end of the second side wall is fixed to the first electrode plate in such a manner that the second semiconductor chip, the second plate electrode, the second columnar electrode, and the second lower step portion are sandwiched between the second upper wall and the first electrode plate, and
the second upper step portion is electrically connected to the second electrode plate.

3. The semiconductor device according to claim 2, wherein
the first insulating frame and the second insulating frame are integrally formed.

4. The semiconductor device according to claim 2, further comprising:
an outer peripheral frame that surrounds the first side wall and the second side wall.

5. The semiconductor device according to claim 4, wherein
a lower end and an upper end of the outer peripheral frame are spaced apart from the first electrode plate and the second electrode plate, respectively.

6. The semiconductor device according to claim 4, wherein
the outer peripheral frame is divided into a first outer peripheral frame that surrounds the first side wall and a second outer peripheral frame that surrounds the second side wall.

7. The semiconductor device according to claim 2, wherein
the first upper wall is formed with a third through hole that penetrates the first upper wall in the thickness direction of the first electrode plate, and
the second upper wall is formed with a fourth through hole that penetrates the second upper wall in the thickness direction of the first electrode plate.

8. The semiconductor device according to claim 2, wherein
an inner wall surface of the first upper wall is formed with irregularities, and
an inner wall surface of the second upper wall is formed with irregularities.

9. The semiconductor device according to claim 2, further comprising:
a first contact pin and a second contact pin; and
an insulating substrate having a wiring pattern,
wherein the first upper wall is formed with a fifth through hole that penetrates the first upper wall in the thickness direction of the first electrode plate,
the second upper wall is formed with a sixth through hole that penetrates the second upper wall in the thickness direction of the first electrode plate,
the first contact pin and the second contact pin are inserted in the fifth through hole and the sixth through hole, respectively,
one end and the other end of the first contact pin are electrically connected to the first semiconductor chip and the wiring pattern, respectively, and
one end and the other end of the second contact pin are electrically connected to the second semiconductor chip and the wiring pattern, respectively.
